(19) United States
(12) Patent Application Publication
(10) Pub. No.: US 2026/0040512 A1
(43) Pub. Date: Feb. 5, 2026

(54) DISPLAY APPARATUS, METHOD OF MANUFACTURING DISPLAY APPARATUS, AND ELECTRONIC DEVICE

(71) Applicant: Samsung Display Co., Ltd., Yongin-si (KR)

(72) Inventors: JUHEE KIM, Yongin-si (KR); CHEULJIN PARK, Yongin-si (KR); JUNHEE SON, Yongin-si (KR)

(21) Appl. No.: 19/205,143

(22) Filed: May 12, 2025

(30) Foreign Application Priority Data
Aug. 1, 2024 (KR) 10-2024-0102300

(51) Int. Cl. H05K 7/20; H10K 59/80

(52) U.S. Cl. CPC H05K 7/20981; H10K 59/8794

(57) ABSTRACT

A display apparatus, a method of manufacturing the display apparatus, and an electronic device including the display apparatus are disclosed. The display apparatus may include a display panel to implement or emit visible light and a heat dissipation member on one surface of the display panel, wherein the heat dissipation member may include a flexible tube to allow at least fluid (e.g., a fluid and/or a solid) to move, a base plate having a groove in one surface thereof, and a cover portion between the base plate and the display panel, and the flexible tube may be in the groove.

### CROSS-REFERENCE TO RELATED APPLICATION

The present application claims priority to and the benefit of Korean Patent Application No. 10-2024-0102300, filed on Aug. 1, 2024, in the Korean Intellectual Property Office, the entire disclosure of which is incorporated herein by reference.

### BACKGROUND

### 1. Field

Aspects of embodiments of the present disclosure relate to a display apparatus, a method of manufacturing the display apparatus, and an electronic device including the display apparatus.

### 2. Description of the Related Art

Electronic devices, such as smartphones, tablet personal computers (PC), digital cameras, laptop computers, a navigation system, smart televisions, and/or the like, that provide images to a user include a display apparatus to display images. A display apparatus includes a display panel that generates and displays images and one or more input devices.

A display device may include a display panel that generates an image through a plurality of light-emitting elements and a heat dissipation member attached to a lower portion of the display panel. A plurality of light-emitting elements of the display panel may display images through power applied from the outside. The plurality of light-emitting elements display images (e.g., via the conversion of power or electrical energy into light energy) through applied power, but some of the power that is not converted into light energy may be emitted outside the display panel in the form of heat energy.

### SUMMARY

One or more embodiments of the present disclosure are directed toward a display apparatus having improved or enhanced manufacturing convenience and heat dissipation characteristics, a method of manufacturing the display apparatus, and an electronic device including the display apparatus.

Additional aspects of embodiments will be set forth in part in the description which follows and, in part, will be apparent from the description, or may be learned by practice of the presented embodiments of the disclosure.

According to one or more embodiments, a display apparatus includes a display panel to implement or emit visible light and a heat dissipation member on one surface of the display panel, wherein the heat dissipation member includes a flexible tube to allow at least fluid (e.g., a fluid and/or a solid) to move, a base plate having one surface on which a groove is formed or provided (or a base plate having a groove in one surface thereof), and a cover portion between the base plate and the display panel, and the flexible tube is in the groove.

In one or more embodiments, the heat dissipation member may further include a filling layer arranged or provided between the base plate and the cover portion and being in contact with the flexible tube.

In one or more embodiments, the filling layer may contain a material that is cured by heat and/or light.

In one or more embodiments, the flexible tube may contain a polymer-based material.

In one or more embodiments, the fluid may contain a coolant that dissipates heat, and the coolant may move in/through an internal space of the flexible tube.

In one or more embodiments, the base plate may further include a stopper that protrudes toward the cover portion based on a thickness direction of the base plate.

In one or more embodiments, the stopper may be arranged or provided to be in contact with the cover portion. In one or more embodiments, the stopper may contact the cover portion.

In one or more embodiments, the groove may be arranged or provided to be bent by changing a direction of the groove at least once to have at least two areas spaced and/or apart (e.g., spaced apart or separated) from each other in a width direction of the groove, and the stopper may be between the at least two areas spaced and/or apart (e.g., spaced apart or separated) from each other in the width direction of the groove. In one or more embodiments, the groove may be bent at least once to extend in different directions and to have a plurality of areas spaced and/or apart (e.g., spaced apart or separated) from each other in a width direction of the groove, and the stopper may be between the areas spaced and/or apart (e.g., spaced apart or separated) from each other in the width direction of the groove.

In one or more embodiments, the groove may include at least two different areas, and the at least two different areas may include areas having different depths. In one or more embodiments, the groove may have a plurality of different areas, and the different areas may have different depths from each other.

In one or more embodiments, the groove may include at least two different areas, and the at least two different areas may include areas having different widths. In one or more embodiments, the groove may have a plurality of different areas, and the different areas may have different widths from each other.

In one or more embodiments, a cross-section of an internal space of the flexible tube, through which the fluid moves, may include at least a curve.

In one or more embodiments, a cross-section of an internal space of the flexible tube, through which the fluid moves, may include at least a polygonal shape.

In one or more embodiments, an internal space of the flexible tube, through which the fluid moves, may include a plurality of spaces spaced and/or apart (e.g., spaced apart or separated) from each other.

In one or more embodiments, the display apparatus may further include a connector into which the flexible tube is inserted, wherein the connector may include an injection port through which the fluid is injected into the flexible tube.

In one or more embodiments, the display panel may include an organic light-emitting element.

In one or more embodiments, the base plate may include at least a metal and/or a polymer.

In one or more embodiments, the cover portion may include at least a metal and/or a polymer.

According to one or more embodiments, a method of manufacturing a display apparatus includes preparing a display panel, preparing a heat dissipation member including a base plate having one surface on which a groove is formed or provided (or including a base plate having a groove in one surface thereof), arranging or providing a filler, which is a material of a filling layer, in the groove, arranging or providing a flexible tube in the groove to be in contact with the filler, after arranging or providing the flexible tube in the groove, covering the flexible tube and the base plate with a cover portion, and attaching the display panel to the heat dissipation member.

In one or more embodiments, the attaching of the display panel to the heat dissipation member may include compressing the display panel and the heat dissipation member between a pair of rolls.

In one or more embodiments, the method may further include curing the filler after inserting the flexible tube into the groove.

According to one or more embodiments, an electronic device includes a display apparatus as described in one or more embodiments.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a cross-sectional view schematically illustrating a display apparatus according to one or more embodiments;

FIG. 2 is an enlarged view schematically illustrating an enlarged example of a region A in FIG. 1;

FIG. 3 is a diagram illustrating a modified example of FIG. 2;

FIG. 4 is a cross-sectional view schematically illustrating an example of a heat dissipation member of FIG. 1;

FIG. 5 is a plan view schematically illustrating an example of the heat dissipation member of FIG. 1;

FIG. 6 is a cross-sectional view schematically illustrating another example of the heat dissipation member of FIG. 1;

FIG. 7 is a cross-sectional view schematically illustrating another example of the heat dissipation member of FIG. 1;

FIG. 8 is a cross-sectional view schematically illustrating another example of the heat dissipation member of FIG. 1;

FIG. 9 is a plan view schematically illustrating another example of the heat dissipation member of FIG. 1;

FIG. 10 is an enlarged view schematically illustrating an enlarged example of a region B in FIG. 9;

FIGS. 11-13 each is a cross-sectional view illustrating an example of a method of manufacturing a heat dissipation member according to one or more embodiments;

FIGS. 14-15 each is a diagram illustrating a method of manufacturing a display apparatus according to one or more embodiments.

FIG. 16 is a block diagram of an electronic device according to one or more embodiments.

FIG. 17 is schematic views of individual electronic devices according to one or more embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term “and/or” includes any and all combinations of one or more of the associated listed items. Expressions, such as “at least one of,” if (e.g., when) preceding a list of elements, modify the entire list of elements and do not modify the individual elements of the list.

As the present disclosure allows for one or more suitable changes and embodiments, certain embodiments will be illustrated in the accompanying drawings and described in more detail in the written description. The aspects, effects, and/or embodiments of the present disclosure and methods of achieving them will be clarified with reference to one or more embodiments and the accompanying drawings described below in more detail. The disclosure may, however, be embodied in one or more different forms and should not be construed as being limited to the embodiments set forth herein.

In the present disclosure, while such terms as “first,” “second,” and/or the like, may be used to describe one or more elements, such elements must not be limited to the above terms.

In the present disclosure, an expression used in the singular encompasses the expression of the plural, unless it has a clearly different meaning in the context.

As utilized herein, the singular forms “a,” “an,” and “the” are intended to include the plural forms as well, unless the context clearly indicates otherwise. Further, the utilization of “may” if (e.g., when) describing embodiments of the present disclosure refers to “one or more embodiments of the present disclosure.”

In the present disclosure, it is to be understood that the terms, such as “include/including” and “have/having,” are intended to indicate the existence of the features, or elements disclosed in the disclosure, and are not intended to preclude the possibility that one or more other features or elements may exist or may be added.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that if (e.g., when) a unit, a region, or an element is referred to as being “on” another unit, region, or element, it may be directly or indirectly on the other unit, region, or element. For example, intervening units, regions, or elements may be present therebetween. In contrast, if (e.g., when) a unit, a region, or an element is referred to as being “directly on” another unit, region, or element, there are no intervening elements present therebetween.

In the present disclosure, the terms, such as connect or couple, do not necessarily refer to a direct and/or fixed connection or coupling of two members, unless the context clearly indicates otherwise, and do not exclude the case where another member is between the two members.

The sizes of elements in the drawings may be exaggerated to effectively or suitably illustrate the technical contents. In one or more embodiments, because the sizes and/or the thicknesses of components in the drawings are arbitrarily illustrated to effectively or suitably illustrate the technical contents, embodiments of the present disclosure are not limited thereto.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

The subject matter of the present disclosure will be described more fully hereinafter with reference to the accompanying drawings, in which embodiments of the present disclosure are shown. Like reference numerals in the drawings denote like elements, and thus their description may not be provided.

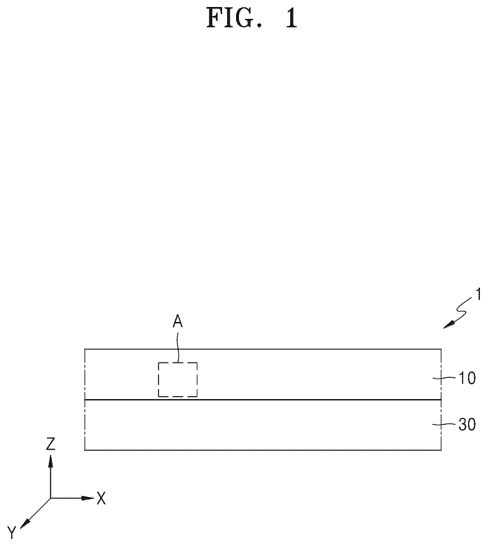

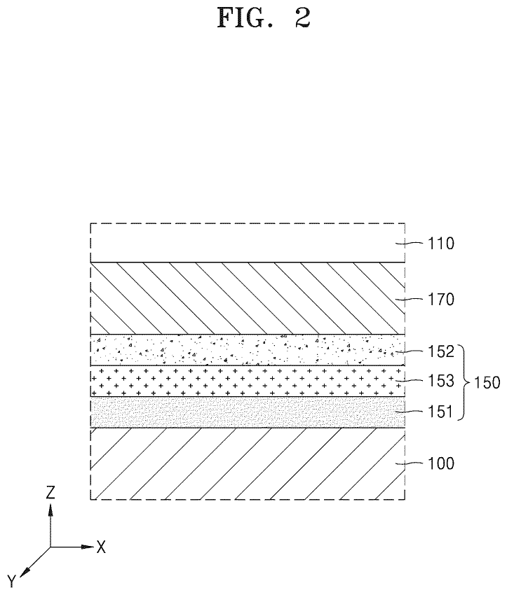

FIG. 1 is a cross-sectional view schematically illustrating a display apparatus according to one or more embodiments, and FIG. 2 is an enlarged view schematically illustrating an enlarged example of a region A of FIG. 1.

Referring to FIG. 1, a display apparatus 1 according to one or more embodiments may implement or emit light (e.g., visible light) in one direction, and for example, the light (e.g., the visible light) may be implemented or emitted to face upward with respect to the drawing.

The display apparatus 1 may have one or more suitable shapes, such as a flat panel shape, or as another example, the display apparatus 1 may also be a bending and/or flexible type or kind.

The display apparatus 1 may be one or more suitable types or kinds. For example, the display apparatus 1 may be a display apparatus, such as an organic light-emitting display apparatus, an inorganic light-emitting display apparatus, or a quantum dot light-emitting display apparatus. Hereinafter, an organic light-emitting display apparatus is described in more detail as an example. The display apparatus 1 may be implemented as one or more suitable types or kinds of electronic devices, such as a mobile phone, a laptop computer, and a smartwatch.

The display apparatus 1 may include a display panel 10 that implements or emits visible light and a heat dissipation member 30 on a surface opposite to one surface of the display panel 10, the one surface that implements or emits visible light. For example, visible light may be implemented or emitted in one direction (e.g., a direction toward the upper side in FIG. 1) from the upper surface of the display panel 10 (for example, the upper surface with respect to FIG. 1). The heat dissipation member 30 may be on the opposite surface (for example, the lower surface with respect to FIG. 1) of one surface (e.g., the surface that implements or emits visible light) of the display panel 10 among the surfaces of the display panel 10, and for example, the heat dissipation member 30 may be connected to the display panel 10 in the form of contact or bonding.

The display panel 10 may include one or more organic light-emitting elements that emit visible light that may be recognized by a user.

Due to certain components and operations to be described in one or more embodiments of the present disclosure, the display apparatus 1 may have relatively low difficulty in bonding a base plate 310 to a cover portion 340 and a low defect rate of the display apparatus 1 caused by a coolant that leaks into a flexible tube 330, and may implement a flow path structure through which one or more suitable types or kinds of coolant may flow, and thus a coolant injection process may be facilitated.

As shown in FIG. 2, the display panel 10 may include a display element 150 capable of implementing or emitting (or configured to implement or emit) visible light to provide visible light to a user. The display element 150 may include one or more suitable types or kinds, and in one or more embodiments, a case where the display element 150 is an organic light-emitting element is described as an example.

The display panel 10 is described in one or more embodiments in more detail. The display panel 10 may include a substrate 100, the display element 150, and an encapsulation member 170.

The substrate 100 may be formed or provided by using one or more suitable materials. For example, the substrate 100 may include a transparent (e.g., substantially transparent) glass material containing silicon dioxide (SiO₂) as a main or predominant component. In one or more embodiments, the substrate 100 may include a transparent (e.g., substantially transparent) plastic material.

The display element 150 may be on the substrate 100 and may include a first electrode 151, a second electrode 152, and an intermediate layer 153. For example, the first electrode 151 may be on the substrate 100, the second electrode 152 may be on the first electrode 151, and the intermediate layer 153 may be between the first electrode 151 and the second electrode 152.

A buffer layer may also be further formed or provided above the first electrode 151 and the substrate 100. The buffer layer may provide a flat (e.g., substantially flat) surface on the substrate 100 and block moisture and/or gas from penetrating through the substrate 100 (or reduce a degree to or occurrence of which moisture and/or gas penetrates through the substrate 100).

The first electrode 151 may function or serve as an anode, and the second electrode 152 may function or serve as a cathode. The order of the polarities of the first electrode 151 and the second electrode 152 may be reversed. If (e.g., when) the first electrode 151 functions or serves as an anode, the first electrode 151 may include ITO, IZO, ZnO, In₂O₃, and/or the like, which has a high work function. In one or more embodiments, depending on the purpose and design conditions, the first electrode 151 may further include a reflective (e.g., substantially reflective) film including silver (Ag), magnesium (Mg), aluminum (Al), platinum (Pt), palladium (Pd), gold (Au), nickel (Ni), neodymium (Nd), iridium (Ir), chromium (Cr), lithium (Li), ytterbium (Yb), calcium (Ca), and/or the like.

If (e.g., when) the second electrode 152 functions or serves as a cathode, the second electrode 152 may include a metal, such as Ag, Mg, Al, Pt, Pd, Au, Ni, Nd, Ir, Cr, Li, Ca, and/or the like. In one or more embodiments, the second electrode 152 may include ITO, IZO, ZnO, In₂O₃, and/or the like to enable light transmission.

The intermediate layer 153 may include at least an organic emission layer. In one or more embodiments, the intermediate layer 153 may selectively include at least one selected from among a hole injection layer, a hole transport layer, an electron transport layer, and an electron injection layer, in addition to the organic emission layer. If (e.g., when) voltage is applied to the first electrode 151 and the second electrode 152, visible light may be generated from the intermediate layer 153, for example, the organic emission layer of the intermediate layer 153.

The encapsulation member 170 may be on the display element 150 to protect the display element 150. The encapsulation member 170 may protect the display element 150 from external impacts (or reduce a degree or occurrence of external impacts on the display element 150) and prevent penetration of external foreign materials and/or moisture (or reduce a degree or occurrence of penetration of external foreign materials and/or moisture).

The encapsulation member 170 may be in one or more suitable types or kinds. In one or more embodiments, the encapsulation member 170 may include a transparent (e.g., substantially transparent) glass material containing silicon dioxide (SiO₂) as a main or predominant component. In one or more embodiments, the encapsulation member 170 may include a plastic material that allows light to pass through. In one or more embodiments, the encapsulation member 170 may be formed or provided by using an inorganic film and/or an organic film. In one or more embodiments, the encapsulation member 170 may be formed or provided by stacking one or more organic films and one or more inorganic films. In one or more embodiments, the encapsulation member 170 may be formed or provided by alternately stacking organic films and inorganic films.

In one or more embodiments, the display panel 10 may further include an optical functional layer 110. The optical functional layer 110 may include a layer to improve or enhance, change, or suitably control characteristics of light (e.g., visible light) implemented or emitted in the display element 150.

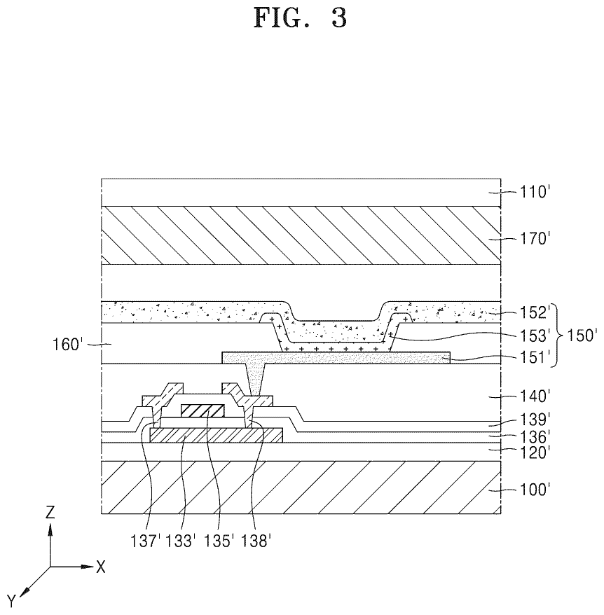

In one or more embodiments, the display panel 10 may include a thin-film transistor to transmit a signal necessary to drive the display element 150 to the display element 150. A more detailed description is made herein with reference to FIG. 3.

FIG. 3 is a diagram illustrating a modified example of FIG. 2. Referring to FIG. 3, the display panel 10 may include a substrate 100′, a display element 150′, a thin-film transistor, and an encapsulation member 170′.

The thin-film transistor may include an active layer 133′, a gate electrode 135′, a source electrode 137′, and a drain electrode 138′. The thin-film transistor is described herein in more detail. A buffer layer 120′ may be on the substrate 100′. The buffer layer 120′ may prevent impurity elements from penetrating through the substrate 100′ (or reduce a degree to or occurrence of which impurity elements penetrate through the substrate 100′) and provide a flat (e.g., substantially flat) surface on the upper portion of the substrate 100′, and may include one or more suitable materials that may perform the functions as described in one or more embodiments. The buffer layer 120′ may be an optional component and may not be provided.

The active layer 133′ may be on the buffer layer 120′ in a set or specific pattern. The active layer 133′ may include an inorganic semiconductor material, such as silicon, may include an organic semiconductor material in one or more embodiments, or may contain an oxide semiconductor material in one or more embodiments.

A gate insulating film 136′ may be on the upper portion of the active layer 133′. The gate insulating film 136′ may include one or more suitable insulating materials, and, for example, the gate insulating film 136′ may be formed or provided by using oxide and/or nitride.

The gate electrode 135′ may be on the upper portion of the gate insulating film 136′ to correspond to a set or specific area of the active layer 133′. The gate electrode 135′ may include a material having relatively good or high conductivity (e.g., electrical conductivity). For example, the gate electrode 135′ may contain Au, Ag, copper (Cu), Ni, Pt, Pd, Al, molybdenum (Mo), and/or the like and may include an alloy, such as an Al:Nd alloy, a Mo:W alloy, and/or the like. However, this is just an example, and embodiments of the present disclosure are not limited thereto, and the gate electrode 135′ may include one or more suitable materials.

An interlayer insulating film 139′ may be formed or provided to cover the gate electrode 135′. The source electrode 137′ and the drain electrode 138′ may be on the interlayer insulating film 139′. The source electrode 137′ and the drain electrode 138′ may be formed or provided to contact set or specific areas of the active layer 133′.

A passivation layer 140′ may be formed or provided to cover the source electrode 137′ and the drain electrode 138′. A separate insulating (e.g., electrically insulating) film may also be further formed or provided on the passivation layer 140′ to planarize the thin-film transistor.

In one or more embodiments, one or more thin-film transistors that may be electrically connected to the display element 150′ may be further included, and one or more capacitors that may be electrically connected to the display element 150′ or the one or more thin-film transistors may be further included.

A first electrode 151′ may be on the passivation layer 140′. The first electrode 151′ may be electrically connected to one of the source electrode 137′ and the drain electrode 138′. For example, the first electrode 151′ may be connected to the drain electrode 138′.

A pixel defining film 160′ may be on the first electrode 151′ and may be formed or provided to expose a set or specific area of the first electrode 151′.

An intermediate layer 153′ may be on the first electrode 151′. The intermediate layer 153′ may include an organic emission layer. In one or more embodiments, the intermediate layer 153′ may further include at least one selected from among a hole injection layer, a hole transport layer, an electron transport layer, and an electron injection layer, in addition to the organic emission layer.

A second electrode 152′ may be on the intermediate layer 153′. The second electrode 152′ may be on the intermediate layer 153′.

The encapsulation member 170′ may be on the display element 150′ to protect the display element 150′.

In one or more embodiments, the display panel 10 may further include an optical functional layer 110′. The optical functional layer 110′ may include a layer to improve or enhance, change, or suitably control one or more suitable characteristics of light (e.g., visible light) implemented or emitted in the display element 150′.

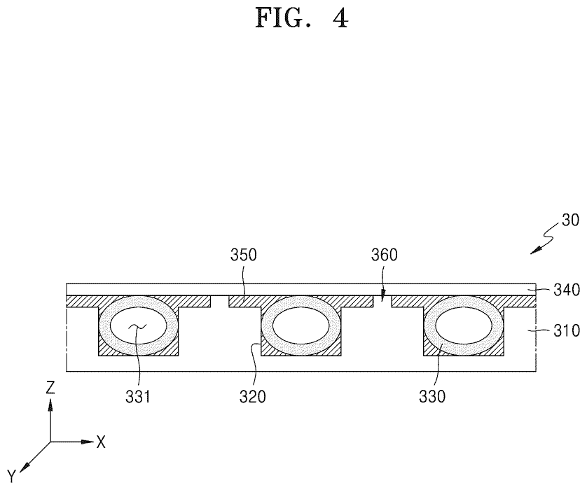

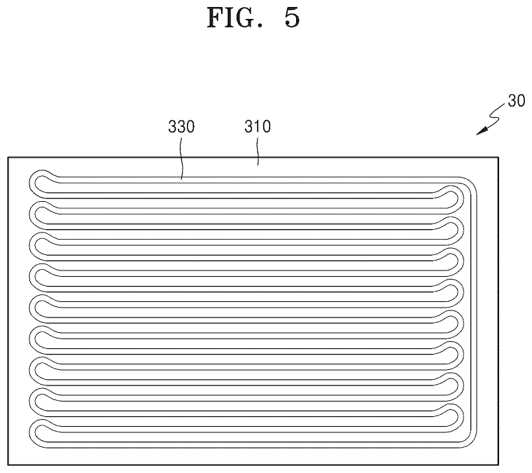

FIG. 4 is a cross-sectional view schematically illustrating an example of the heat dissipation member of FIG. 1, and FIG. 5 is a plan view schematically illustrating an example of the heat dissipation member of FIG. 1.

Referring to FIG. 4, the heat dissipation member 30 may include a base plate 310, a flexible tube 330, a cover portion 340, and a filling layer 350.

For example, the flexible tube 330, which is formed or provided to allow at least fluid (e.g., a fluid and/or a solid) to move, may be in a groove 320 that is on one surface of the base plate 310, the cover portion 340 may be between the base plate 310 and the display panel 10, and the filling layer 350 may be between the base plate 310 and the cover portion 340.

In one or more embodiments, a stopper 360 that protrudes from the base plate 310 toward the cover portion 340 may be further arranged or provided.

A more detailed description is made herein.

The base plate 310 may have one or more suitable shapes, for example, the base plate 310 may have a plate shape (e.g., a substantially plate shape) that corresponds to the display panel 10, and, for example, the base plate 310 may have a plate shape (e.g., a substantially plate shape) having an area that corresponds to the display panel 10. As another example, the base plate 310 may be formed or provided to be smaller than the display panel 10 or, as another example, may be formed or provided to be larger than the display panel 10.

As an example, the base plate 310 may have a thickness (in a Z-axis direction in FIG. 4) and a width and length in a direction perpendicular (e.g., substantially perpendicular) to the thickness, and the width and length may have values that are at least greater than the thickness.

In one or more embodiments, as an example, the base plate 310 may have a polygonal (e.g., substantially polygonal) plan shape, and, for example, the base plate 310 may have a rectangular (e.g., substantially rectangular) plan shape.

The material of the base plate 310 may vary. For example, the base plate 310 may include a flexible material to facilitate easy bonding with the display panel 10, for example, lamination bonding. For example, the base plate 310 may include at least a polymer and/or a metal. In one or more embodiments, the base plate 310 may include a material having relatively high thermal conductivity to absorb heat of the display panel 10 well.

The groove 320 may be on one surface of the base plate 310. The groove 320 may be a flow path through which a coolant flows.

The groove 320 may be on one surface of the base plate 310 to form or provide at least one path. For example, a closed loop may be formed or provided as one path. In one or more embodiments, the groove 320 may also form or provide a plurality of closed loops.

Also, the groove 320 may be on one surface of the base plate 310 in a desired length and shape to control the length and area of a flow path through which a coolant flows on the one surface of the base plate 310.

The groove 320 may be arranged or provided to be curved by changing the direction thereof at least once to have two or more areas that are spaced and/or apart (e.g., spaced apart or separated) in the width direction of the groove 320.

As an example, the groove 320 may have a structure formed or provided by forming or providing long (e.g., forming or providing to extend) on one surface of the base plate 310 in one direction, for example, in a direction parallel (e.g., substantially parallel) to the one surface of the base plate 310, and then repeating a process of changing the direction thereof and forming or providing long (e.g., forming or providing to extend) in the direction parallel (e.g., substantially parallel) to the one surface of the base plate 310 by at least one time, for example, a plurality of times.

In one or more embodiments, the groove 320 may be formed or provided from near one vertex of the base plate 310 along one surface (e.g., an x-axis or y-axis in FIG. 1) adjacent to the one vertex, and may be formed or provided from the one surface adjacent to the one vertex to another surface by being rotated 180° toward the opposite vertex of the one vertex before reaching the other surface adjacent to the one surface, and thus, the groove 320 may be defined from the one surface to the opposite surface of the one surface in the method as described in one or more embodiments. The groove 320 may form or provide one closed loop.

The flexible tube 330 may be inserted into the groove 320, and the flexible tube 330 may be fixed to the groove 320 with a filler.

The flexible tube 330 may be in the groove 320 of the base plate 310. Accordingly, as an example, the flexible tube 330 may also form or provide a closed loop as shown in FIG. 5 along the groove 320.

A fluid, for example, a coolant, may flow within the flexible tube 330. The coolant in the flexible tube 330 may absorb heat generated by the display panel 10 to reduce the temperature of the display panel 10. In one or more embodiments, the material of the flexible tube 330 may be a material having relatively high thermal conductivity.

The fluid may include a coolant for heat dissipation, and the coolant may move in/through an internal space 331 of the flexible tube 330.

One or more suitable coolants may be arranged or provided and flow in the flexible tube 330, which is a closed loop. For example, a coolant in a gaseous or liquid form may be arranged or provided.

As an example, a coolant containing a mixture of two different phases (e.g., liquid and gaseous) of coolants may also be arranged or provided. If (e.g., when) a set or specific area of the display panel 10 generates heat, a coolant in the flexible tube 330, which overlaps the heat-generated portion of the display panel 10, may absorb the heat of the display panel 10, and a set or specific amount of the coolant in a liquid phase at the portion that overlaps the heat-generated portion may be transferred to a coolant in a gaseous phase, and thus, the flow of coolant within the flexible tube 330, which is a closed loop, may become faster, and the heat of the display panel 10 may be absorbed quickly.

In one or more embodiments, the coolant may flow into the internal space 331 of the flexible tube 330 to separate the coolant from the base plate 310, thereby reducing the problem of mutual influence and unnecessary reactivity between the coolant and the base plate 310 from occurring.

In one or more embodiments, one or more suitable coolants may be selected by solving the problem of reactivity between the base plate 310 and the coolant.

In one or more embodiments, as the coolant flows in the flexible tube 330, a problem of fluid leakage due to a defect in bonding of the base plate 310 and the 340, a problem in which a flow path through which a coolant flows is blocked due to the remaining auxiliary materials, such as filler materials for bonding between the base plate 310 and the cover portion 340, and a problem in the resistance of fluid according to the quality of a machined surface of the groove 320 may be alleviated in a structure in which fluid flows in the groove 320 between the base plate 310 and the cover portion 340.

The flexible tube 330 may be of a material having bending or flexible characteristics to correspond to the groove 320 having a curve or the shape of the cover portion 340 or to correspond to the groove 320 having a plurality of bends or the shape of the cover portion 340. For example, the flexible tube 330 may contain a polymer-based material.

Also, for example, the flexible tube 330 may include a silicon material.

The flexible tube 330 according to one or more embodiments may easily or suitably implement multiple flow paths and may be arranged or provided to have a large contact area with the base plate 310 and the cover portion 340, and thus the flexible tube 330 may receive more heat generated from the display panel 10.

In one or more embodiments, the flexible tube 330 may be flexible, thereby having one or more suitable shapes depending on the shape and height of the groove 320 and the degree of compression by the cover portion 340. Also, a plurality of flow paths may also be formed or provided with one flexible tube 330.

The flexible tube 330 may define at least the internal space 331 through which fluid flows. As an example, the cross-section of the internal space 331 through which fluid moves in the flexible tube 330 may include a curve. Due to factors, such as the shape and height of the groove 320, the cross-section of the internal space 331 through which fluid moves in the flexible tube 330 may have one or more suitable shapes, such as a polygonal shape and/or the like.

The flexible tube 330 may be fixed between the groove 320 and the cover portion 340 by the filling layer 350.

In the case of the flexible tube 330, a coolant may be injected directly into the flexible tube 330 and an injection port may be blocked again, and thus the difficulty of a coolant injection process may be lower than the case where a coolant flows between the groove 320 and the cover portion 340.

The cover portion 340 may be arranged or provided to cover the base plate 310 and the flexible tube 330 inserted into the groove 320.

The cover portion 340 may be bonded to the base plate 310.

For example, the cover portion 340 and the base plate 310 may be bonded to each other with a filler of the filling layer 350. In one or more embodiments, the cover portion 340 and the base plate 310 may be bonded to each other by using one or more suitable mechanical bonding methods and/or chemical bonding methods. Also, an opposite surface of one surface of the cover portion 340 may be bonded to the display panel 10, the one surface being bonded to the base plate 310. As an example, the cover portion 340 and the display panel 10 may be bonded to each other through a roll-lamination process.

If (e.g., when) a coolant flows in the groove 320 rather than inside the flexible tube 330, the entire product of the display apparatus 1 may become defective even if (e.g., when) the base plate 310 and the cover portion 340 are not perfectly or suitably bonded to each other and a bonding defect occurs only in a local portion. For example, regardless of whether the base plate 310 and the cover portion 340 include substantially the same material or different materials, the difficulty of bonding the base plate 310 and the cover portion 340 to each other may be high, and lifting of the cover portion 340 may occur.

In one or more embodiments, even if (e.g., when) a coolant flows inside the flexible tube 330 and the base plate 310 and the cover portion 340 are not perfectly or suitably bonded to each other, the heat dissipation member 30 may not be damaged, and the display apparatus 1 having good quality may also be generated with bonding between the base plate 310 and the cover portion 340 at a degree that pressure to the flexible tube 330 may be maintained.

The material of the cover portion 340 may include one or more suitable materials, for example, a flexible material, and, for example, the cover portion 340 may include substantially the same material as the base plate 310. As an example, the material of the cover portion 340 may include at least a polymer and/or a metal.

The base plate 310 and the cover portion 340 may be directly bonded to each other, in addition to a portion where the base plate 310 and the cover portion 340 are bonded to each other with the filling layer 350. As for the direct bonding portion, if (e.g., when) both (e.g., simultaneously) the base plate 310 and the cover portion 340 include metal, the base plate 310 and the cover portion 340 may be bonded to each other by a spot welding method, a riveting method, and/or the like.

In one or more embodiments, if (e.g., when) both (e.g., simultaneously) the base plate 310 and the cover portion 340 include polymer materials or include different materials, such as a polymer or metal, the base plate 310 and the cover portion 340 may be bonded to each other by heat fusion, ultrasonic fusion, and/or the like.

The filling layer 350 may be between the base plate 310 and the cover portion 340. In one or more embodiments, the filling layer 350 may be arranged or provided to contact at least one area of the flexible tube 330.

For example, after filling the groove 320 of the base plate 310 with a filler, the filler may overflow from the groove 320 as the flexible tube 330 is seated in the groove 320. The overflowed filler may form or provide the filling layer 350 as the base plate 310 and the cover portion 340 are bonded to each other, and the filler of the filling layer 350 may help bond the base plate 310 and the cover portion 340 to each other.

The filling layer 350 may contain a curable filler. As an example, the filling layer 350 may contain a material that is cured by heat and/or light.

After the groove 320 is filled with a filler, the flexible tube 330 may be inserted into the groove 320, and then the filler may be cured, and the flexible tube 330 may be fixed to the groove 320 by the cured filler.

In one or more embodiments, the cover portion 340 may be covered over the filler that overflows from the groove 320 and the flexible tube 330, so that the cover portion 340 and the base plate 310 may be bonded to each other, and the filler may be cured again. The cured filler may form or provide the filling layer 350 and adhere the base plate 310 to the cover portion 340 to prevent the risk of damage (or reduce a degree or occurrence of the risk of damage) to the heat dissipation member 30.

The filling layer 350 formed or provided of an adhesive filler may bond the base plate 310, the cover portion 340, and the flexible tube 330 to each other to reduce or prevent a problem of coolant leakage due to poor or weak bonding between the base plate 310 and the cover portion 340 in a structure that allows fluid to flow in the groove 320 between the base plate 310 and the cover portion 340. In one or more embodiments, if (e.g., when) a coolant leaks due to a defect in the flexible tube 330, the filling layer 350 may also prevent secondary coolant leakage (or reduce a degree or occurrence of secondary coolant leakage).

The filling layer 350 may include one or more suitable materials, may include a resin-based material, or may contain a curable material, for example, a photo-curable resin-based material and/or a heat-curable resin-based material.

In one or more embodiments, the base plate 310 may further include a stopper 360. The stopper 360 may have a protruding shape, for example, may have a protruding shape in a thickness direction of the base plate 310 toward the cover portion 340 based on the thickness direction of the base plate 310.

The stopper 360 may be formed or provided to be at least spaced and/or apart (e.g., spaced apart or separated) from the groove 320. The stopper 360 may be between two areas spaced and/or apart (e.g., spaced apart or separated) in a width direction of the groove 320. For example, the stopper 360 may be between two areas of neighboring grooves 320 in the width direction of the groove 320 (for example, the X-axis direction in FIG. 4).

For example, a plurality of stoppers 360 (for example, two stoppers as shown in FIG. 4) may be between a portion of the groove 320 that extends along one surface of the base plate 310 and a portion of the groove 320 that overlaps the portion in a vertical (e.g., substantially vertical) direction of the one surface.

In one or more embodiments, the stopper 360 may have a structure that extends long, for example, a structure that extends long in a longitudinal direction (for example, the Y-axis direction in FIG. 4) of the groove 320. For example, the stopper 360 may also have a length that at least corresponds to the length of the groove 320 in one direction.

As an example, the stopper 360 may be arranged or provided to be bonded to the cover portion 340.

For example, at least one stopper 360 may be bonded to the cover portion 340 to maintain or provide the compressed state of the flexible tube 330 and reinforce or enhance the bonding between the base plate 310 and the cover portion 340. In one or more embodiments, the stopper 360 and the cover portion 340 may be bonded to each other by one or more suitable methods, such as welding, a riveting method, heat fusion, ultrasonic fusion, and/or the like.

For example, the stopper 360 may protrude in the thickness direction of the base plate 310 to increase an area where a filler may contact the base plate 310 and the cover portion 340, thereby reinforcing or enhancing the bonding between the base plate 310 and the cover portion 340.

The stopper 360 may prevent fluid from leaking out of the heat dissipation member 30 (or reduce a degree to or occurrence of which fluid leaks out of the heat dissipation member 30) while being bonded to the cover portion 340. As an example, the stopper 360 may be spot welded to the cover portion 340 to reinforce or enhancing the bonding thereof.

A degree of compression of the flexible tube 330 may be adjusted depending on the presence or absence of the stopper 360 and the degree of height of the stopper 360. Assuming that the groove 320 has substantially the same depth, the lower the height of the stopper 360 is, the greater the degree of compression of the flexible tube 330 may be.

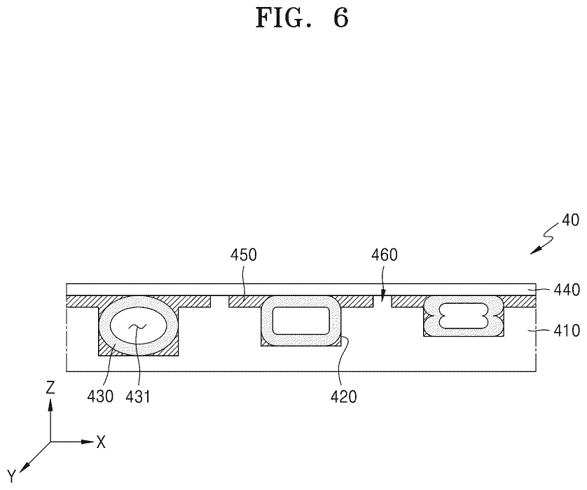

FIG. 6 is a cross-sectional view schematically illustrating another example of the heat dissipation member of FIG. 1. A heat dissipation member 40 may include a base plate 410 including a groove 420, a flexible tube 430 inserted into the groove 420, a cover portion 440 that covers the base plate 410 and the flexible tube 430, and a filling layer 450 between the base plate 410 and the cover portion 440.

The flexible tube 430, which is formed or provided to allow at least fluid (e.g., a fluid and/or a solid) to move, may be in the groove 420 that is on one surface of the base plate 410, the cover portion 440 may be between the base plate 410 and the display panel 10, and the filling layer 450 may be between the base plate 410 and the cover portion 440.

In one or more embodiments, a stopper 460 that protrudes from the base plate 410 toward the cover portion 440 may be further arranged or provided between two areas of neighboring grooves 420 in a width direction (e.g., an X-axis direction) of the groove 420.

Referring to FIG. 6, the groove 420 as an example may form or provide at least two or more different areas, and the two or more different areas may have different depths. For example, as shown in FIG. 6, the groove 420 may include a first area having the deepest depth (e.g., a groove in the left area of FIG. 6), a second area having the shallowest depth (e.g., a groove in the right area of FIG. 6), and a third area having a depth at a level between the two depths as described in one or more embodiments. This is an example, and the groove 420 may have two or more areas having different depths, and as another example, the groove 420 may have four or more areas having different depths.

In one or more embodiments, the groove 420 may form or provide at least two different areas, and the at least two different areas may have different widths. In one or more embodiments, the groove 420 may have a plurality of different areas, and the different areas may have different widths from each other. As another example, the groove 420 may have four or more areas having different widths.

As the shape and height of certain portions in the groove 420, which is one closed loop, are adjusted, the flexible tube 430 seated in the groove 420 may be transformed into one or more suitable shapes even within one heat dissipation member 40.

If (e.g., when) the heat dissipation member 40 is used to include the groove 420 having areas having different depths and/or widths, the area of a flow path through which a coolant flows may be precisely or suitably controlled, and a dissipation effect of heat generated in the display panel 10 may be improved or enhanced.

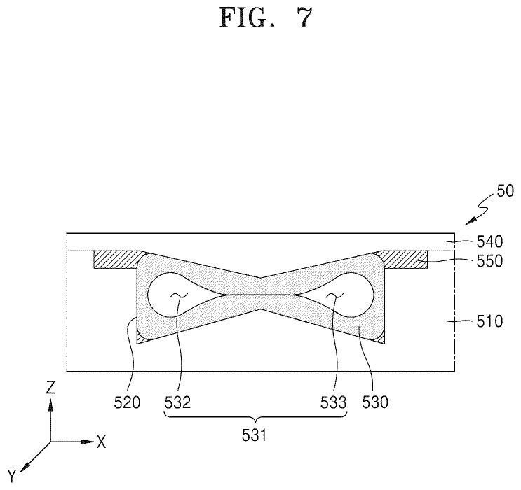

FIG. 7 is a cross-sectional view schematically illustrating another example of the heat dissipation member of FIG. 1.

A heat dissipation member 50 may include a base plate 510 including a groove 520, a flexible tube 530 inserted into the groove 520, a cover portion 540 that covers the base plate 510 and the flexible tube 530, and a filling layer 550 between the base plate 510 and the cover portion 540.

For example, the flexible tube 530, which is formed or provided to allow at least fluid (e.g., a fluid and/or a solid) to move, may be in the groove 520 that is on one surface of the base plate 510, the cover portion 540 may be between the base plate 510 and the display panel 10, and the filling layer 550 may be between the base plate 510 and the cover portion 540.

In one or more embodiments, a stopper 560 that protrudes from the base plate 510 toward the cover portion 540 may be further arranged or provided between two areas of neighboring grooves 420 in a width direction (e.g., an X-axis direction of FIG. 7) of the groove 520.

Referring to FIG. 7, the groove 520 in one example may be formed or provided to have areas having different depths in the width direction (e.g., the X-axis direction of FIG. 7) thereof. For example, the groove 520 may have areas having the deepest depth that corresponds to the edges on both sides with respect to the width direction, and an area therebetween may be shallower in depth. For example, the groove 520 may have the largest depth value in the areas that correspond to the edges on both sides with respect to the width direction, and the depth value of a central area therebetween may be the smallest. For example, the groove 520 may have a protruding shape in which an area (e.g., the central area) between the edges on both sides with respect to the width direction faces the cover portion 540.

In one or more embodiments, the cover portion 540 may have a protruding shape so that the area (e.g., the central area) between the areas that correspond to the edges on both sides with respect to the width direction of the groove 520 faces toward the base plate 510 than the areas that correspond to the edges on both sides with respect to the width direction of the groove 520.

Depending on the depth to the bottom of the groove 520 or a degree to which the cover portion 540 protrudes into the flexible tube 530, the central area of one flexible tube 530 or an area adjacent thereto may be bonded to define two separate internal spaces 531.

The internal spaces 531 of the flexible tube 530, through which a fluid moves, may include a first space 532 and a second space 533 spaced and/or apart (e.g., spaced apart or separated) from the first space 532.

In one or more embodiments, a space inside one flexible tube 530 may be divided into a plurality of spaces to improve or enhance precise or suitable control characteristics of a coolant flow path. For example, in a mechanically processed groove of a base plate, it may be difficult to reduce the distance between a groove portion that extends along one surface of a base plate in a rectangular (e.g., substantially rectangular) shape and a groove portion that overlaps the groove portion in a vertical (e.g., substantially vertical) direction of the one surface, while in the heat dissipation member 50 in one or more embodiments of FIG. 7, two flow paths may be formed or provided with one flexible tube 530, thereby relieving restrictions on the distance between groove portions that overlap each other in the vertical (e.g., substantially vertical) direction of the one surface.

As an example, as the shape and height of certain portions in the groove 520, which is one closed loop, are adjusted, the flexible tube 530 seated in the groove 520 may be transformed into one or more suitable shapes even within one heat dissipation member 50.

If (e.g., when) the heat dissipation member 50 in which the internal spaces 531 of one flexible tube 530 includes the first space 532 and the second space 533 spaced and/or apart (e.g., spaced apart or separated) therefrom is used by adjusting the depth to the bottom of the groove 520 or the degree to which the cover portion 540 protrudes into the flexible tube 530, the area of a flow path through which a coolant flows may be precisely or suitably controlled, and a dissipation effect of heat generated in the display panel 10 may be improved or enhanced.

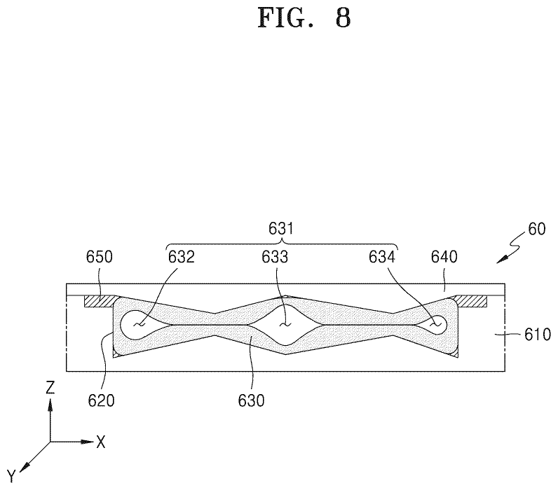

FIG. 8 is a cross-sectional view schematically illustrating another example of the heat dissipation member of FIG. 1.

A heat dissipation member 60 may include a base plate 610 including a groove 620, a flexible tube 630 inserted into the groove 620, a cover portion 640 that covers the base plate 610 and the flexible tube 630, and a filling layer 650 between the base plate 610, which is flexible, and the cover portion 640.

For example, the flexible tube 630, which is formed or provided to allow at least fluid (e.g., a fluid and/or a solid) to move, may be in the groove 620 that is on one surface of the base plate 610, the cover portion 640 may be between the base plate 610 and the display panel 10, and the filling layer 650 may be between the base plate 610 and the cover portion 640.

In one or more embodiments, a stopper 660 that protrudes from the base plate 610 toward the cover portion 640 may be further arranged or provided between two areas of neighboring grooves 620 in a width direction (e.g., an X-axis direction of FIG. 8) of the groove 620.

The groove 620 may form or provide a plurality of protrusion portions at the bottom of the groove 620, and the cover portion 640 may also form or provide a plurality of protrusion portions that faces the flexible tube 630. Referring to FIG. 8, the groove 620 in one example may include two protrusion portions at the bottom, and the cover portion 640 may include two protrusion portions that face the flexible tube 630.

As the cover portion 640 and the base plate 610 are bonded to each other, a plurality of bonding areas may be created or provided in the flexible tube 630 by the protrusion portions at the bottom of the groove 620 and the protrusion portions of the cover portion 640, and accordingly, a plurality of internal spaces 631 may be defined. Referring to FIG. 8, in the flexible tube 630 of one example, two bonding areas may be created or provided by two protrusion portions at the bottom of the groove 620 and two protrusion portions of the cover portion 640, and the internal spaces 631 may include a first space 632, a second space 633, and a third space 634, which are spaced and/or apart (e.g., spaced apart or separated) from each other.

In one or more embodiments, a space inside one flexible tube 630 may be divided into a plurality of spaces to improve or enhance precise or suitable control characteristics of a coolant flow path. For example, in a mechanically processed groove of a base plate, it may be difficult to reduce the distance between a groove portion that extends along one surface of the base plate in a rectangular (e.g., substantially rectangular) shape and a groove portion that overlaps the groove portion in a vertical (e.g., substantially vertical) direction of the one surface, while in the heat dissipation member 60 in one or more embodiments of FIG. 8, a plurality of flow paths may be formed or provided with one flexible tube 630, thereby relieving restrictions on the distance between groove portions that overlap each other in the vertical (e.g., substantially vertical) direction of the one surface.

As an example, as the shape and height of certain portions in the groove 620, which is one closed loop, are adjusted, the flexible tube 630 seated in the groove 620 may be transformed into one or more suitable shapes even within one heat dissipation member 60.

If (e.g., when) a plurality of bonding areas of the groove 620 and the cover portion 640 are created or provided and the heat dissipation member 60 in which the internal spaces 631 of one flexible tube 630 includes the first space 632, the second space 633, and the third space 634, which are spaced and/or apart (e.g., spaced apart or separated) from each other, is used by adjusting the depth to the bottom of the groove 620 or a degree to which the cover portion 640 protrudes into the flexible tube 630, the area of a flow path through which a coolant flows may be precisely or suitably controlled, and a dissipation effect of heat generated in the display panel 10 may be improved or enhanced.

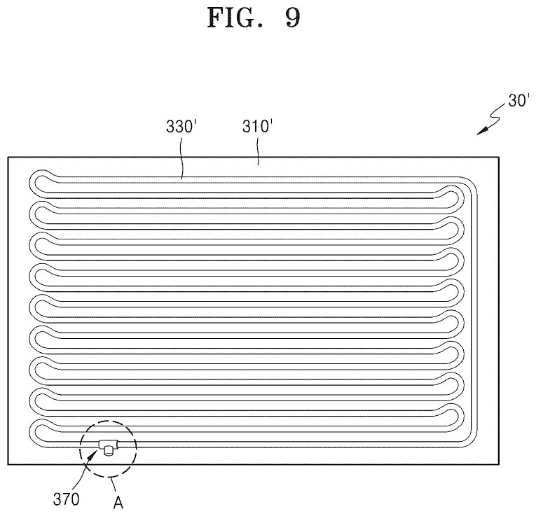

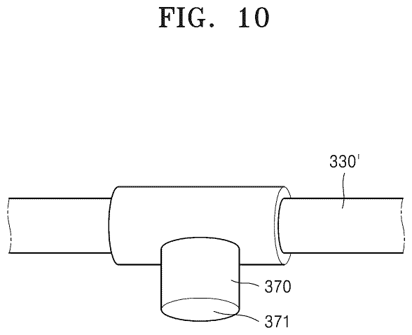

FIG. 9 is a plan view schematically illustrating another example of the heat dissipation member of FIG. 1, and FIG. 10 is an enlarged view schematically illustrating an example of an enlarged region B of FIG. 9.

The heat dissipation member 30′ may further include a connector 370 into which a flexible tube 330′ is inserted. At least one area of the flexible tube 330′ may be connected to the connector 370, and, for example, the connector 370 may be connected to the flexible tube 330′ to communicate with an internal space 331 of the flexible tube 330′. For example, two ends of the flexible tube 330′ may be connected to the connector 370.

In one or more embodiments, a valve may be added to the connector 370 to adjust a coolant injected into the flexible tube 330′. The valve may be connected to the connector 370, the internal space 331 of the flexible tube 330′ may be made to a vacuum state, the flexible tube 330′ may be filled with a set or specific amount of a coolant, and then the flexible tube 330′ may be finished to simplify a coolant injection process.

The connector 370 may further include a separate injection port 371 in addition to a hole into which the flexible tube 330′ is inserted. In one or more embodiments, even if (e.g., when) a coolant is re-injected or additionally injected due to problems, such as defects, the process may be facilitated because the coolant may be injected by piercing the finished flexible tube 330′ at the injection port 371.

In one or more embodiments, the connector 370 may be connected to the flexible tube 330′ closest to one surface of the base plate 310 in a rectangular (e.g., substantially rectangular) shape as an example. In one or more embodiments, the injection port 371 may facilitate the addition or re-injection of a coolant from the outside of the heat dissipation member 30′ toward the inside of the heat dissipation member 30′.

After injecting the coolant, the injection port 371 may be blocked. For example, an openable cover or an insertion member inserted into the injection port 371 may be additionally arranged or provided at the injection port 371 to block the injection port 371.

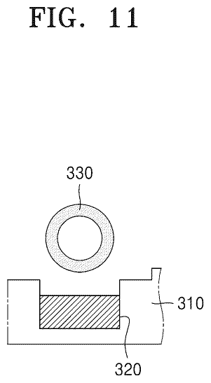

FIGS. 11 to 13 are cross-sectional views illustrating an example of a method of manufacturing a heat dissipation member according to one or more embodiments.

For example, FIGS. 11 to 13 are diagrams illustrating a process of manufacturing the heat dissipation member 30 of FIG. 4 as an example. This is for convenience of explanation, and a manufacturing method according to one or more embodiments may also be applied to the heat dissipation members 40, 50, and 60 of the other embodiments as described in one or more embodiments in substantially the same way or modified to a similar extent as desired or required.

Hereinafter, for convenience of explanation, the heat dissipation member 30 of FIG. 4 is described as an example.

Referring to FIG. 11, the groove 320 in which the flexible tube 330 may be seated may be machined in the base plate 310. The processed groove 320 may serve as a flow path through which fluid flows.

A filler may be applied to the processed groove 320. For example, the filler that becomes the material of the filling layer 350 may be in the groove 320. The filler may be a curable material and may include a resin-based material. In one or more embodiments, the filler may have properties of relatively high thermal conductivity to transfer heat generated from the display panel 10.

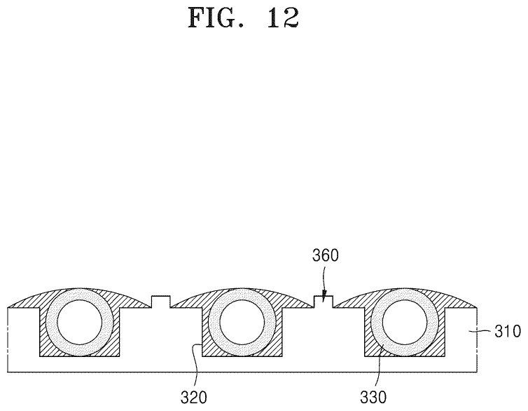

Referring to FIG. 12, the flexible tube 330 may be placed or provided in the groove 320 to be in contact with the filler. If (e.g., when) the flexible tube 330 is inserted into the groove 320 to which the filler has been applied, the filler may overflow out of the groove 320, and in this state, the filler may be primarily cured. The primary curing may prevent the flexible tube 330 from moving (or reduce a degree to or occurrence of which the flexible tube 330 moves) due to the filler in the groove 320 and may fix the position of the flexible tube 330. For example, if (e.g., when) curing the filler, thermal curing may be used.

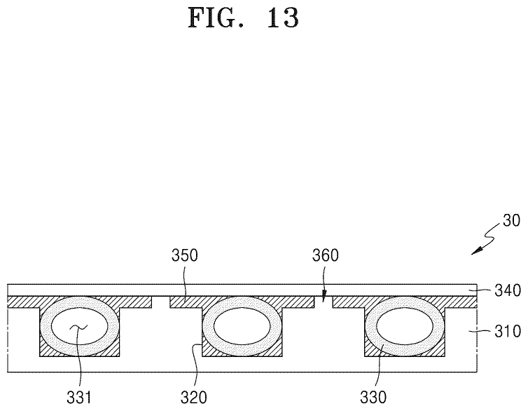

Referring to FIG. 13, after curing the filler, the cover portion 340 may be moved from the base plate 310 onto the cured filler and the flexible tube 330. As an example, a heat press jig may pick up the cover portion 340 and transfer substantially the same onto the cured filler and the flexible tube 330.

After the cover portion 340 is placed on the filler and the flexible tube 330, heat and pressure may be applied to the cover portion 340. In one or more embodiments, the secondary curing of the filler may be performed, and the base plate 310, the cover portion 340, and the flexible tube 330 may be attached to each other. The secondary curing may structurally stabilize the flexible tube 330 within the groove 320 covered by the cover portion 340 by completely fixing the flexible tube 330 with the filling layer 350.

If (e.g., when) a coolant flows directly into a flow path between the groove 320 and the cover portion 340, a defect in which the coolant leaks from the base plate 310 and the cover portion 340 of the heat dissipation member 30 may easily occur, while as in one or more embodiments, the coolant flows within the flexible tube 330, and the occurrence of defects in which the coolant leaks may be reduced or prevented by the arrangement of the filling layer 350 in addition to the flexible tube 330.

In one or more embodiments, through stable control of a coolant flow path, the base plate 310 and the cover portion 340 may not be damaged, and the base plate 310 and the cover portion 340 may be bonded to each other at a degree that the pressure of the flexible tube 330 may be maintained at a set or specific level. As an example, the base plate 310 and the cover portion 340 may be bonded to each other by spot-welding one or more of the stoppers 360 among the plurality of stoppers 360 included in the base plate 310 to the cover portion 340.

As the cover portion 340 is bonded to the stopper 360, the flexible tube 330 may be compressed by being pressed against the cover portion 340. In one or more embodiments, depending on the shape and depth of the groove 320, the flexible tube 330 may have one or more suitable shapes while being pressed against the cover portion 340. In one or more embodiments, depending on the shape of the cover portion 340, the flexible tube 330 may have one or more suitable shapes.

After the base plate 310 and the cover portion 340 are bonded to each other, a coolant may be charged into the flexible tube 330. For example, after connecting both ends of the flexible tube 330 with a connector (for example, refer to 370 in FIGS. 9 and 10) and installing a valve on the connector 370, the internal space 331 of the flexible tube 330 may be made to a vacuum state, and the flexible tube 330 may be charged with a set or specific amount of a coolant through the injection port 371, and then the flexible tube 330 may be finished.

The heat dissipation member 30 may be manufactured through the operations as described in one or more embodiments in FIGS. 11 to 13.

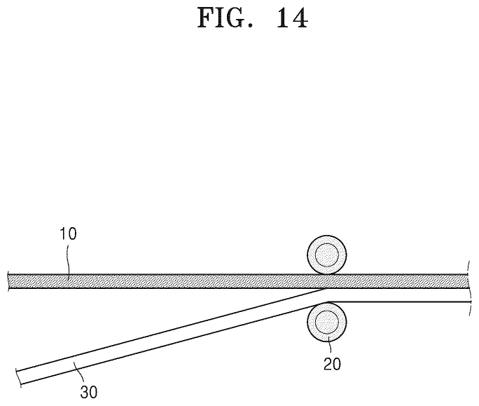

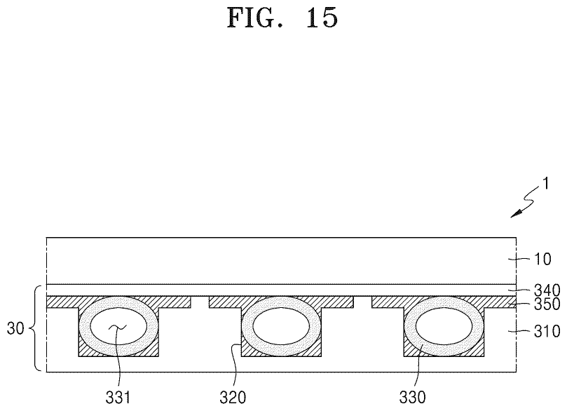

FIGS. 14 and 15 are diagrams illustrating a method of manufacturing a display apparatus according to one or more embodiments.

Referring to FIG. 14, attaching the display panel 10 and the heat dissipation member 30 to each other is shown. For convenience of explanation, FIG. 14 illustrates one heat dissipation member 30 among the heat dissipation members as described in one or more embodiments. This is for convenience of explanation, and the heat dissipation members 40, 50, and 60 of the other embodiments as described in one or more embodiments may be substantially equally applied to the method of manufacturing a display apparatus according to one or more embodiments or may be modified to a similar extent as desired or required.

Hereinafter, for convenience of explanation, the heat dissipation member 30 is described as an example.

The display panel 10 and the heat dissipation member 30 may be separately prepared and attached to each other. The display panel 10 and the heat dissipation member 30 may be attached to each other through one or more suitable methods. As an example, the display panel 10 of a flat panel and the heat dissipation member 30 may be bonded to each other by using a roll-lamination process in which two layers are pressed together by using a pair of rolls 20 to be bonded to each other.

Through the bonding process of the display panel 10 and the heat dissipation member 30, the display apparatus 1 may be manufactured as shown in FIG. 15.

The manufacturing method according to one or more embodiments may easily or suitably manufacture the display apparatus 1 by easily or suitably attaching the display panel 10 to the heat dissipation member 30, and, for example, the display apparatus 1 having a large area may be efficiently or suitably manufactured.

In the display apparatus 1 of one example, the heat dissipation member 30 may be on one surface of the display panel 10, one surface of the cover portion 340 of the heat dissipation member 30 may be directly bonded to the display panel 10, another surface of the cover portion 340 may be bonded to the base plate 310, and the flexible tube 330 inserted into the groove 320 of the base plate 310 and the filling layer 350 between the flexible tube 330, the cover portion 340, and the base plate 310 may be included.

Through the operations as described in one or more embodiments, the display apparatus 1 having the structure as described in one or more embodiments may have a low difficulty in bonding between the base plate 310 and the cover portion 340 and a low defect rate of the display apparatus 1 due to coolant leakage within the flexible tube 330, and may implement a flow path structure through which one or more suitable types or kinds of coolant may flow, and thus a coolant injection process may be facilitated.

The display apparatus 1 may further include a housing which accommodates the display panel 10 and a heat dissipation member 30. For example, the heat dissipation member 30 may be between the housing and the display panel 10.

The display apparatus 1 according to one or more embodiments may be applied to one or more suitable electronic devices 1000. An electronic device 1000 according to one or more embodiments may include the display apparatus 1 as described in one or more embodiments, and may further include a module or device having additional functions, in addition to the display apparatus 1.

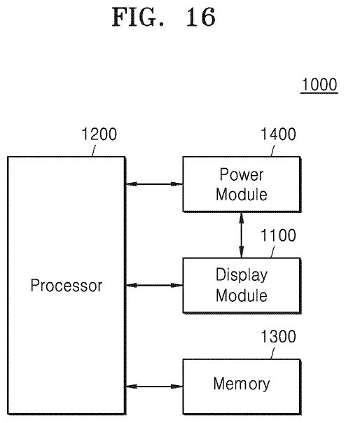

FIG. 16 is a block diagram of an electronic device according to one or more embodiments. Referring to FIG. 16, an electronic device 1000 according to one or more embodiments may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information desired or required for the operation of the processor 1200 or the display module 1100. An image data signal and/or an input control signal may be transmitted to the display module 1100 in case that the processor 1200 executes an application stored in the memory 1300, and the display module 1100 may output image information through a display screen by processing the received signal.

The power module 1400 may include a power supply module, such as a power adapter and/or a battery device, and a power conversion module which converts power supplied by the power supply module to generate power desired or required for the operation of the electronic device 1000.

At least one of respective components of the electronic device 1000 may be included in the display apparatus 1 according to one or more embodiments. In one or more embodiments, one or more of the individual modules that are functionally included in a module may be included in a display apparatus, while others may be provided separately from the display apparatus. For example, the display apparatus 1 may include the display module 1100, and the processor 1200, the memory 1300, and the power module 1400 may be provided in the form of other apparatuses in the electronic device 1000 other than the display apparatus 1.

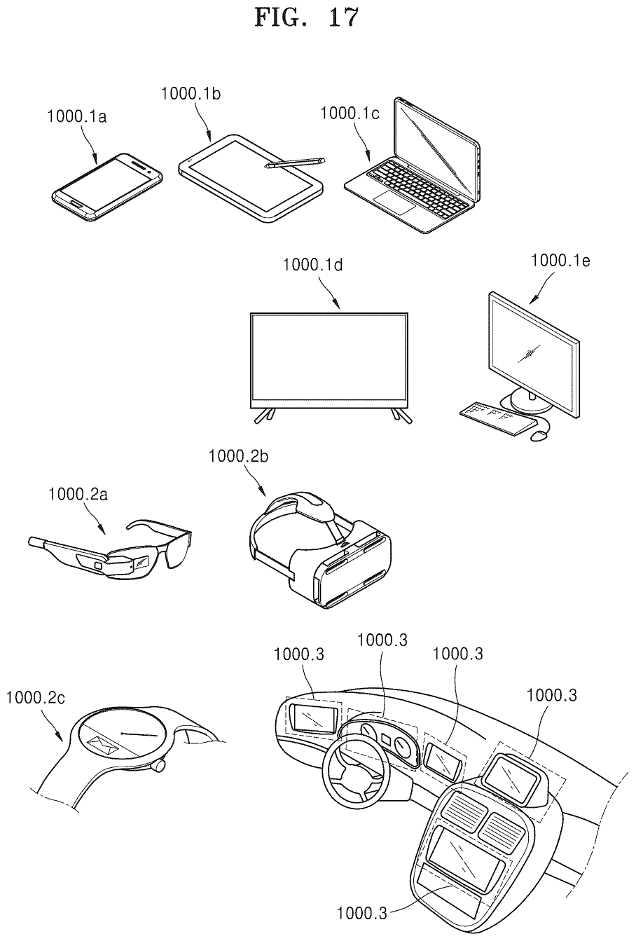

FIG. 17 illustrates schematic views of individual electronic devices according to one or more embodiments.

Referring to FIG. 17, one or more suitable electronic devices according to one or more embodiments, to which the display apparatus 1 is applied, may include: an electronic device to display an image, such as a smart phone 1000.1a, a tablet PC 1000.1b, a laptop computer 1000.1c, a TV set 1000.1d, a desk monitor 1000.1e, and/or the like; a wearable electronic device including a display module, such as smart glasses 1000.2a, a head mounted display 1000.2b, a smart watch 1000.2c, and/or the like; and an electronic device 1000.3 for vehicles including a display module, such as a center information display (CID) on an instrument panel, center fascia, or dashboard of a vehicle, a room mirror display, and/or the like.

Each of the embodiments as described herein may be implemented independently, but the structure of each embodiment may be applied in combination to other embodiments.

A display apparatus, a method of manufacturing the display apparatus, and an electronic device including the display apparatus according to one or more embodiments may improve or enhance manufacturing convenience and heat dissipation characteristics.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

Certain implementations described in one or more embodiments are examples and do not limit the scope of the embodiments in any way. In one or more embodiments, if (e.g., when) there is no specific mention, such as “essential,” “important,” and/or the like, it may not be a necessary component for the application of the disclosure.

The use of the term “above” and similar referential terms in the present disclosure (e.g., in the claims) may refer to both (e.g., simultaneously) the singular and the plural. In one or more embodiments, if (e.g., when) a range is described in one or more embodiments, the disclosure includes the application of individual values within the range (unless there is a statement to the contrary), and is substantially the same as describing each individual value that constitutes the range in the more detailed description. Finally, unless the order of the operations that constitutes the method according to one or more embodiments is clearly stated or there is no description to the contrary, the operations may be performed in an appropriate or suitable order. Embodiments of the present disclosure are not necessarily limited by the order of description of the operations in the present disclosure. The use of all examples or illustrative terms in the present disclosure is simply to explain the embodiments in more detail, and the scope of the embodiments is not limited by the examples or illustrative terms unless limited by the claims. In one or more embodiments, those skilled in the art will recognize that one or more suitable modifications, combinations, and changes may be made depending on the design conditions and factors within the scope of the appended claims or their equivalents.

What is claimed is:

1. A display apparatus comprising:
a display panel to emit visible light; and
a heat dissipation member on one surface of the display panel, the heat dissipation member comprising:
a flexible tube to allow fluid to move;
a base plate having a groove in one surface thereof; and
a cover portion between the base plate and the display panel,
wherein the flexible tube is in the groove.

2. The display apparatus as claimed in claim 1, wherein:
the heat dissipation member further comprises a filling layer between the base plate and the cover portion and in contact with the flexible tube.

3. The display apparatus as claimed in claim 2, wherein:
the filling layer comprises a material that is cured by heat or light.

4. The display apparatus as claimed in claim 1, wherein:
the flexible tube comprises a polymer-based material.

5. The display apparatus as claimed in claim 1, wherein:
the fluid comprises a coolant, and
the coolant moves through an internal space of the flexible tube.

6. The display apparatus as claimed in claim 1 wherein:
the base plate further comprises a stopper that protrudes toward the cover portion based on a thickness direction of the base plate.

7. The display apparatus as claimed in claim 6, wherein:
the stopper contacts the cover portion.

8. The display apparatus as claimed in claim 6, wherein:
the groove is bent at least once to extend in different directions and to have a plurality of areas spaced apart from each other in a width direction of the groove, and
the stopper is between the areas spaced apart from each other in the width direction of the groove.

9. The display apparatus as claimed in claim 1, wherein:
the groove has a plurality of different areas, and
the different areas have different depths from each other.

10. The display apparatus as claimed in claim 1, wherein:
the groove has a plurality of different areas, and
the different areas have different widths from each other.

11. The display apparatus as claimed in claim 1, wherein:
a cross-section of an internal space of the flexible tube, through which the fluid moves, comprises a curve.

12. The display apparatus as claimed in claim 1, wherein:
a cross-section of an internal space of the flexible tube, through which the fluid moves, comprises a polygonal shape.

13. The display apparatus as claimed in claim 1, wherein:
an internal space of the flexible tube, through which the fluid moves, comprises a plurality of spaces spaced apart from each other.

14. The display apparatus as claimed in claim 1, further comprising a connector into which the flexible tube is inserted,
wherein the connector comprises an injection port through which the fluid is injected into the flexible tube.

15. The display apparatus as claimed in claim 1, wherein:
the display panel comprises an organic light-emitting element.

16. The display apparatus as claimed in claim 1, wherein:
the base plate comprises a metal or a polymer.

17. The display apparatus as claimed in claim 1, wherein:
the cover portion comprises a metal or a polymer.

18. A method of manufacturing a display apparatus, the method comprising:
preparing a display panel;
preparing a heat dissipation member comprising a base plate having a groove in one surface thereof;
providing a filler, which is a material of a filling layer, in the groove;
providing a flexible tube in the groove to be in contact with the filler;
after providing the flexible tube in the groove, covering the flexible tube and the base plate with a cover portion; and
attaching the display panel to the heat dissipation member.

19. The method as claimed in claim 18, wherein:
the attaching of the display panel to the heat dissipation member comprises compressing the display panel and the heat dissipation member between a pair of rolls.

20. The method as claimed in claim 18, further comprising:
curing the filler after inserting the flexible tube into the groove.

21. An electronic device comprising:
a display module comprising:
a display panel to emit visible light; and
a heat dissipation member on one surface of the display panel, the heat dissipation member comprising:
a flexible tube to allow fluid to move;
a base plate having a groove in one surface thereof, the flexible tube being in the groove; and
a cover portion between the base plate and the display panel;
a processor;
a memory; and
a power module.
